(19) United States
(12) Patent Application Publication
(10) Pub. No.: US 2025/0016963 A1
(43) Pub. Date: Jan. 9, 2025

(54) ELECTRICALLY ISOLATING THERMAL INTERFACE MODULE FOR LOW VOLTAGE ELECTRICAL DEVICES

(71) Applicant: Schneider Electric USA, Inc.

(72) Inventors: Timothy R. FABER, Marion, IA (US); Cameron Lee WOODSON, Jr., Cedar Rapids, IA (US); Clinton Neal CARNE, North Liberty, IA (US); Randy Wiliiam BLAKE, Vinton, IA (US); Daniel Gene HOLLINGER, Ceder Rapids, IA (US)

(73) Assignee: Schneider Electric USA, Inc., Boston, MA (US)

(21) Appl. No.: 18/279,750

(22) PCT Filed: Mar. 8, 2023
(86) PCT No.: PCT/US2023/014781

§ 371 Date: Aug. 31, 2023

Related U.S. Application Data
(60) Provisional application No. 63/317,811, filed on Mar. 8, 2022.

(51) Int. Cl. H05K 7/20; H01H 9/52; H02G 5/10

(52) U.S. Cl. CPC H05K 7/20472; H01H 9/52; H02G 5/10

(57) ABSTRACT

Apparatuses, systems, and methods are provided for an electrically isolating thermal interface device. The system may include a power source, a thermal dissipation element, and a thermal interface module coupleable between the power source and the thermal dissipation element, the thermal interface module including a first interface coupleable to the power source, a second interface coupleable to the thermal dissipation element, a housing coupleable between the first interface and the second interface, an interface module configured to provide a thermal path from the first interface to the second interface, a first film coupleable between the first interface and the interface module, and a second film coupleable between the second interface and the interface module.

### RELATED APPLICATION

The present application claims priority to U.S. Provisional Patent Application Ser. No. 63/317,811, filed on Mar. 8, 2022, and entitled ELECTRICALLY ISOLATING THERMAL INTERFACE MODULE FOR LOW VOLTAGE ELECTRICAL DEVICES, which is incorporated by reference herein in its entirety.

### TECHNICAL FIELD

The present disclosure relates to heat transfer devices, and more particularly, to electrically isolating thermal interface modules.

### BACKGROUND

Conventional systems in the world of internal arc management suffer problems in relation to the need for better arc management (e.g., stronger enclosures, reduced venting), which is at conflict with the needs for efficient cooling. Currently, the users of newer arc management systems are forced to use complex active systems or reduced current ratings in order to accommodate the thermal reality. Thus, problems arise in relation to providing arc management functionality while meeting or exceeding the heat transfer efficiency of pre-arc management designs.

### SUMMARY

Implementations consistent with the present disclosure may provide one or more solutions to problems referenced above and experienced in the field, amongst other problems solved by implementations according to the present disclosure. Furthermore, a means to return or exceed the heat transfer efficiency of the pre-arc management designs would be most welcome by those in the art.

Implementations consistent with the present disclosure may provide the ability for an advanced passive arc management system (e.g., such as in an ArcBlok or other arc management implementation) to achieve better than typical thermal performances while maintaining a form factor compatible with existing norms and which allows for the necessary compaction of power conductor systems in incorporation of sub-enclosures. Implementations consistent with the present disclosure may provide benefits in relation to limiting exposure to electronics via an enclosure. Implementations consistent with the present disclosure may enable electrically isolating thermal interface modules for low voltage electrical devices which is capable of use well beyond 12-24V applications, for example extending to 40-600V or more applications (for example, up to 1000 VAC or 1500 VDC applications), thereby providing a host of benefits beyond any previous alternatives. Various components described herein may be selected or implemented based at least in part upon having a highly thermally conductive characteristic.

Implementations consistent with the present disclosure may include a module configured to provide very efficient thermal transfer (e.g., on the order of a few degrees Celsius per 100 W) and simultaneously provide electrical isolation well in the kV range in a package that is robust on a commercial/industrial degree for handling, installation/removal/maintenance, environmental resistance, etc. This module may form a link between an energized current path in a component like a circuit breaker or busbar on the interior of an electrical equipment enclosure and a heat dissipation device that could be located exterior to the equipment and hence need to be maintained at ground potential. Additionally or alternatively, a module may be used for line to line conductors to transfer heat between phases in various embodiments. Implementations consistent with the present disclosure may unlock the ability for an advanced passive arc management system (e.g., an ArcBlok implementation or other arc management system) to achieve, better than typical thermal performances while maintaining a form factor compatible with existing norms and allowing for the necessary compaction of power conductor systems in incorporation of sub-enclosures.

Taken together, the combination of insulating, conductive, and mechanical materials create a compact, efficient package capable of use across a plurality of fields, and not just limited to arc management systems.

According to aspects of the present disclosure, provided is a thermal interface module which may be coupleable to a heat sink element. The thermal interface module may include one or more of a first interface, a second interface, a housing coupleable between the first interface and a second interface, an interface module configured to provide a thermal path to the heat sink element, a first film coupleable between the first interface and the interface module, and a second film coupleable between the second interface and the interface module.

According to further aspects of the present disclosure, provided is a system for providing an electrically isolating thermal interface. The system includes a power source (e.g., at an energized section), a thermal dissipation element (e.g., such as a heat sink element at a grounded section); and a thermal interface module coupleable between the power source and the thermal dissipation element. The thermal interface module may include a first interface coupleable to the power source, a second interface coupleable to the thermal dissipation element, a housing coupleable between the first interface and the second interface, an interface module configured to provide a thermal path from the first interface to the second interface, a first film coupleable between the first interface and the interface module, and a second film coupleable between the second interface and the interface module.

Implementations consistent with the present disclosure may include a thermal interface module device coupleable to a heat sink element. The thermal interface module may include a first interface, a second interface, a housing coupleable between the first interface and the second interface, an interface module configured to provide a thermal path to the heat sink element, a first film coupleable between the first interface and the interface module, and a second film coupleable between the second interface and the interface module. The first interface may be an energized interface plate. The second interface may be a grounded interface plate. The interface module may be a ceramic material. The interface module may be an aluminum oxide material. The aluminum oxide material may be alumina. The first film and the second film may provide isolation layers.

Further aspects of the present disclosure may include a system for providing an electrically isolating thermal interface. The system may include a power source, a thermal dissipation element, and a thermal interface module device coupleable between the power source and the thermal dissipation element. The thermal interface module device may include a first interface coupleable to the power source, a second interface coupleable to the thermal dissipation element, a housing coupleable between the first interface and the second interface, an interface module configured to provide a thermal path from the first interface to the second interface, a first film coupleable between the first interface and the interface module, and a second film coupleable between the second interface and the interface module.

The first interface may be an energized interface plate. The second interface may be a grounded interface plate. The interface module may be a ceramic material. The interface module may be an aluminum oxide material. The aluminum oxide material may be alumina. The first film and the second film may provide isolation layers. The thermal dissipation element may dissipate heat shared between phases of a plurality of power sources.

According to still further aspects, implementations consistent with the present disclosure may include a method for providing a thermal interface module device between a power source and a thermal dissipation element. The method may include providing first interface in contact with the power source, providing a second interface in contact with the thermal dissipation element, providing a housing between the first interface and the second interface, providing an interface module implementing a thermal path from the first interface and the second interface, providing a first film in contact with the first interface and the interface module, and providing a second film in contact with the second interface and the interface module.

Numerous other objects, features, and advantages of the present invention will be readily apparent to those skilled in the art upon a reading of the following disclosure when taken in conjunction with the accompanying drawings

### BRIEF DESCRIPTION OF THE DRAWINGS

FIG. 1 illustrates a raised perspective view of an embodiment of a module (e.g., a Thermal Interface Module) according to aspects of the present disclosure.

FIG. 2 illustrates a partial exploded view of an embodiment of the module of FIG. 1 according to aspects of the present disclosure.

FIG. 3 illustrates a partial raised internal perspective view of a system implementing the module of FIGS. 1-2 according to aspects of the present disclosure.

FIG. 4 illustrates a partial raised perspective view of a mounted configuration of the module of FIGS. 1-2 according to aspects of the present disclosure.

FIG. 5 illustrates an exploded view of an embodiment of a module (e.g., a Thermal Interface Module) according to aspects of the present disclosure.

A more detailed description of the disclosure, briefly summarized above, may be had by reference to various embodiments, some of which are illustrated in the appended drawings. While the appended drawings illustrate select embodiments of this disclosure, these drawings are not to be considered limiting of its scope, for the disclosure may admit to other equally effective embodiments.

Identical reference numerals have been used, where possible, to designate identical elements that are common to the figures. However, elements disclosed in one embodiment may be beneficially utilized on other embodiments without specific recitation.

### DETAILED DESCRIPTION

Aspects of the present disclosure may provide implementations whereby a device includes the ability to create a safe (e.g., electrically isolating, mechanically robust) and efficient (e.g., cost, size, performance) link between an energized current path and a grounded or isolated heat sink. This may address needs in low-voltage electrical equipment. Aspects of the present disclosure may include a multi-layer voltage isolation system in which each layer is independently capable of resisting the necessary ordinary and extra-ordinary voltage isolation requirements in one or more (or all) expected operating conditions and modes of conventional electrical equipment including resistance to environment conditions like dust and humidity and handling stresses consistent with installation, operation and maintenance. This may be accomplished by a very simple construction, for example emulating a fuse, in which the housing may act as a high strength mechanical “shell” that encapsulates and protects the inner isolation layers as well as providing basic electrical over-surface clearances.

At the top and bottom may be interface plates, one of which is intended to be energized (which may be either interface plate) and another interface plate that is intended to be grounded or coupled to another energized phase. One or more elements of interface plates may be of different shapes and/or sizes, for example to ensure that required electrical clearances are respected, in coordination with the isolation layers (e.g., film, ceramic, or the like), and minimize the thermal impedance of a device so as to remove the maximum amount of thermal energy using only the smallest amount of differential temperature to do so. In addition, the device may be configured to be installed and removed in the field by electrical technicians under a similar level of expertise as installing cables or power connectors. It could be that some additional care might be needed in terms of interface conditions (e.g., thermal grease), which, at worst, would emulate current practices like, for example, the installation of a micro-processor in the motherboard of a personal computer.

Implementations consistent with the present disclosure may increase the thermal efficiency of a low voltage device. In existing systems, heat is dissipated through circuit breaker surfaces or attached conductors. Implementations consistent with the present disclosure may allow for a purposeful thermal path to an external heat sink. One or more heat sinks useable according to the present disclosure may be configured in a manner such that they must be grounded (e.g., when a heat sink extends outside of an enclosure).

As described herein, an embodiment of the compilation of layered insulators may include a) a high thermal conductive ceramic core that establishes dielectric over surface, and b) highly conforming upper and lower films. One or more implementations may include a mechanically robust fuse-like housing. Various embodiments may include one or more components which function as a dust and/or moisture barrier.

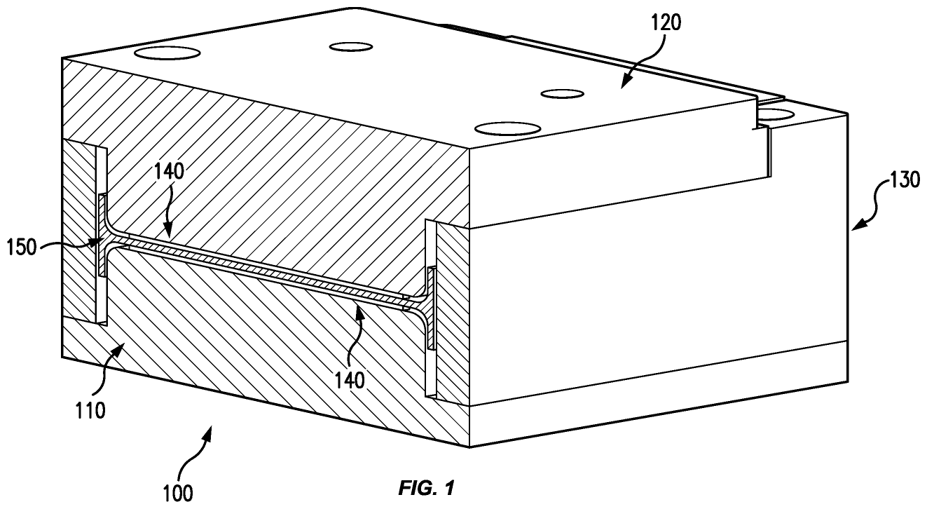

FIG. 1 illustrates a raised perspective view of an embodiment of a module according to aspects of the present disclosure. The module 100 includes one or more of a first interface 110 (e.g., first interface plate), a second interface 120 (e.g., second interface plate), a housing 130, at least one film 140, and/or an interface module 150. The first interface plate 110 may be a lower core (e.g., as an energized interface plate). The second interface plate 120 may be an upper core (e.g., as a grounded interface plate). The housing 130 may be a thermal interface. For example, the housing 130 may be an insulated housing. The at least one film 140 may include a thermal interface material. The interface module 150 may be an insulated interface module.

Although described as a film, it should be appreciated that one or more film 140 may be any material in any shape or size which is capable of performing one or more aspects of film 140 described herein, without departing from the spirit and scope of the present disclosure. The interface module 150 may be formed of or otherwise include an aluminum oxide material (e.g., alumina) in various embodiments. The interface module 150 may be used to move heat from one or more lugs to one or more external heat sinks.

In various configurations, the system may be configured to be certified to Underwriter Laboratories (UL) 489 standard spacings and/or other industrial electrical equipment spacings such as IEC 60947-1. For uses beyond arc management implementations, systems consistent with the present disclosure may be UL certified (e.g., 845, 891, 1558) in regard to spacing requirements. One or more spacings associated with the module 100 may be configured to conform to one or more required UL standard(s) spacings, such as a minimum spacing between live parts of opposite polarity of one-half inch for voltages between 0-130V, three-quarters of an inch between 130-250V, and one inch through air for voltages between 250-1,000V to conform to the requirements of UL 891. Additionally or alternatively, a minimum spacing between terminals and grounded metal as used in the system may be one-half inch for voltages between parts of 0-1000V through air and 0-300V over surface and may be one inch for voltages between parts of 301-1000V over surface. In various exemplary embodiments, the thermal interface material used for one or more insulation layers may be a material having sufficient thermal and conductive properties to permit the module 100 to operate in the manner described herein (such as T-work9000 by LiPOLY, a liquid metal embedded elastomer by Arieca, or other material).

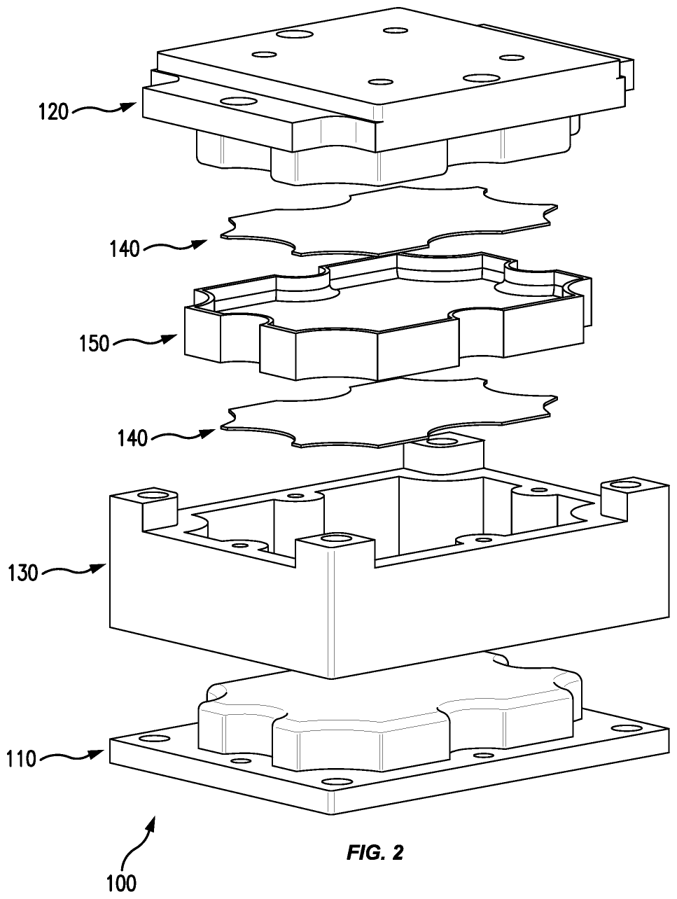

FIG. 2 illustrates a partial exploded view of an embodiment of the module of FIG. 1 according to aspects of the present disclosure. As illustrated by FIG. 2, the module 100 may include a plurality of components sandwiched between the first interface plate 110 and the second interface plate 120. The housing 130 may be placed between the first interface plate 110 and a film 140. The film 140 in contact with the housing 130 may be configured between the housing 130 and the interface module 150. Additionally or alternatively, the film 140 may be configured as to be floating relative to the housing 130. In such embodiments, an over surface configuration may be used to ensure isolation. Still further, in various embodiments, a clamped joint between elements of the module may be used to seal off the upper and lower cores (e.g., first interface plate 110 and second interface plate 120) from one another. In such configuration, no air path exists between the upper and lower cores within the module 100. The interface module 150 may be configured between a plurality of films 140. At least one film 140 may be configured between the interface module 150 and the second interface plate 120.

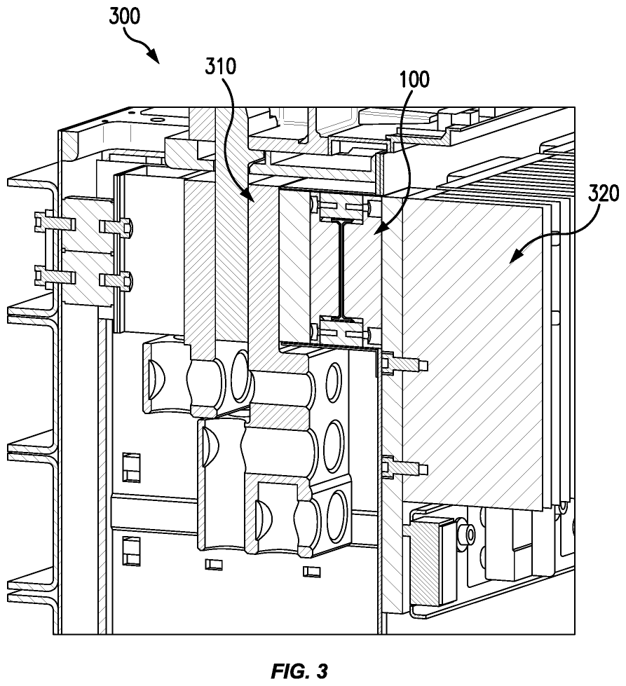

FIG. 3 illustrates a partial raised internal perspective view of a system implementing the module of FIGS. 1-2 according to aspects of the present disclosure. The system 300 includes the module 100 coupled between an energized section 310 and a grounded section 320. The grounded section 320 may include at least one heatsink element coupleable to the module 100, for example at one of the first interface plate 110 or the second interface plate 120. At least one thermal sensor (not illustrated, e.g., a Easergy CL110 Wireless Environmental Sensor for Continuous Condition Monitoring, available from Schneider Electric) may be coupleable to or otherwise associated with one or more elements of the system 300, for example at the grounded section 320, optionally at a heat sink element thereof.

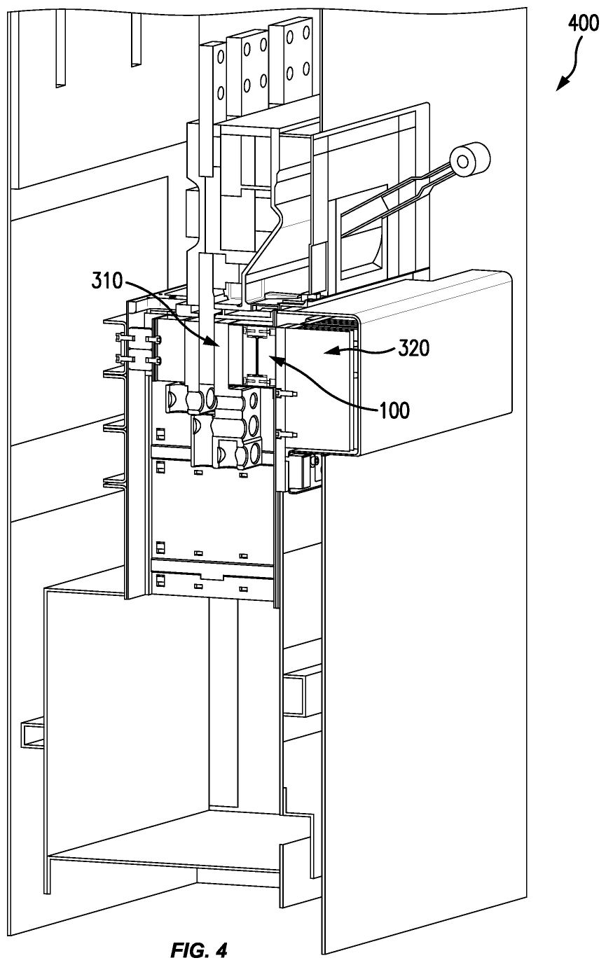

FIG. 4 illustrates a partial raised perspective view of a mounted configuration of the module of FIGS. 1-2 according to aspects of the present disclosure. A structure 400 may be configured to receive and/or couple to one or more elements of the module 100, for example at one or more of the energized section 310 or the grounded section 320 thereof. At least a portion of the grounded section 320 may include a housing or shielding component.

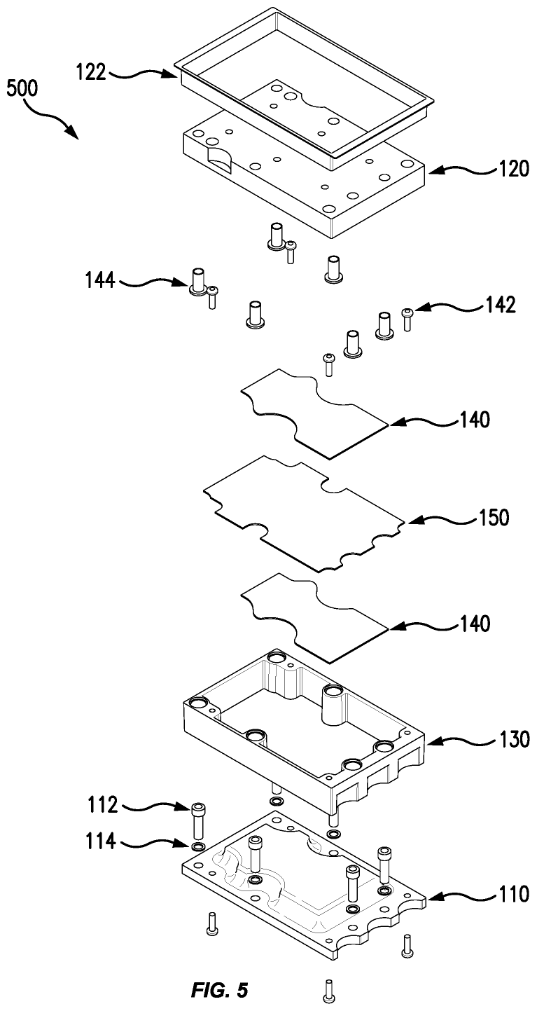

FIG. 5 illustrates an exploded view of an embodiment of a module 500 according to aspects of the present disclosure. The module 500 may include one or more components of a module 100, along with an optional cover 122 coupleable to an upper core (e.g., second interface 120), one or more coupling elements 142, one or more sleeves 144, one or more films (e.g., film 140), an interface module 150, a housing 130, a lower core (e.g., first interface 110), one or more fasteners 112, and/or one or more washers 114.

A thermal interface module 100 may be coupleable to a heat sink element (e.g., at a grounded section 320). The thermal interface module 100 may include one or more of a first interface 110, a second interface 120, a housing 130 coupleable between the first interface 110 and a second interface 120, an interface module 150 configured to provide a thermal path to the heat sink element, a first film 140 coupleable between the first interface 110 and the interface module 150, and a second film 140 coupleable between the second interface 120 and the interface module 150.

Implementations consistent with the present disclosure include a system for providing an electrically isolating thermal interface. The system includes a power source (e.g., at the energized section 310), a thermal dissipation element (e.g., such as a heat sink element at the grounded section 320); and a thermal interface module 100 coupleable between the power source and the thermal dissipation element. The thermal interface module may include a first interface 110 coupleable to the power source, a second interface 120 coupleable to the thermal dissipation element, a housing 130 coupleable between the first interface 110 and the second interface 120, an interface module 150 configured to provide a thermal path from the first interface 110 to the second interface 120, a first film 140 coupleable between the first interface 110 and the interface module 150, and a second film 140 coupleable between the second interface 120 and the interface module 150.

Implementations consistent with the present disclosure may include a thermal interface module device coupleable to a heat sink element. The thermal interface module may include a first interface, a second interface, a housing coupleable between the first interface and the second interface, an interface module configured to provide a thermal path to the heat sink element, a first film coupleable between the first interface and the interface module, and a second film coupleable between the second interface and the interface module. The first interface may be an energized interface plate. The second interface may be a grounded interface plate. The interface module may be a ceramic material. The interface module may be an aluminum oxide material. The aluminum oxide material may be alumina. The first film and the second film may provide isolation layers.

Further aspects of the present disclosure may include a system for providing an electrically isolating thermal interface. The system may include a power source, a thermal dissipation element, and a thermal interface module device coupleable between the power source and the thermal dissipation element. The thermal interface module device may include a first interface coupleable to the power source, a second interface coupleable to the thermal dissipation element, a housing coupleable between the first interface and the second interface, an interface module configured to provide a thermal path from the first interface to the second interface, a first film coupleable between the first interface and the interface module, and a second film coupleable between the second interface and the interface module.

The first interface may be an energized interface plate. The second interface may be a grounded interface plate. The interface module may be a ceramic material. The interface module may be an aluminum oxide material. The aluminum oxide material may be alumina. The first film and the second film may provide isolation layers. The thermal dissipation element may dissipate heat shared between phases of a plurality of power sources.

According to still further aspects, implementations consistent with the present disclosure may include a method for providing a thermal interface module device between a power source and a thermal dissipation element. The method may include providing first interface in contact with the power source, providing a second interface in contact with the thermal dissipation element, providing a housing between the first interface and the second interface, providing an interface module implementing a thermal path from the first interface and the second interface, providing a first film in contact with the first interface and the interface module, and providing a second film in contact with the second interface and the interface module.

In the preceding, reference is made to various embodiments. However, the scope of the present disclosure is not limited to the specific described embodiments. Instead, any combination of the described features and elements, whether related to different embodiments or not, is contemplated to implement and practice contemplated embodiments. Furthermore, although embodiments may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

The various embodiments disclosed herein may be implemented as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer-readable medium(s) having computer-readable program code embodied thereon.

Computer program code for carrying out one or more operations for aspects of the present disclosure or otherwise related to one or more operations for aspects of the present disclosure may be written in any combination of one or more programming languages. Moreover, such computer program code can execute using a single computer system or by multiple computer systems communicating with one another (e.g., using a local area network (LAN), wide area network (WAN), the Internet, etc.). While various features in the preceding are described with reference to flowchart illustrations and/or block diagrams, a person of ordinary skill in the art will understand that each block of the flowchart illustrations and/or block diagrams, as well as combinations of blocks in the flowchart illustrations and/or block diagrams, can be implemented by computer logic (e.g., computer program instructions, hardware logic, a combination of the two, etc.). Generally, computer program instructions may be provided to a processor(s) of a general-purpose computer, special-purpose computer, or other programmable data processing apparatus. Moreover, the execution of such computer program instructions using the processor(s) produces a machine that can carry out a function(s) or act(s) specified in the flowchart and/or block diagram block or blocks.

Block diagrams in the Figures may illustrate the architecture, functionality and/or operation of possible implementations of various embodiments of the present disclosure. In this regard, each block in any flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It is to be understood that the above description is intended to be illustrative, and not restrictive. Many other implementation examples are apparent upon reading and understanding the above description. Although the disclosure describes specific examples, it is recognized that the systems and methods of the disclosure are not limited to the examples described herein but may be practiced with modifications within the scope of the appended claims. Accordingly, the specification and drawings are to be regarded in an illustrative sense rather than a restrictive sense. The scope of the disclosure should, therefore, be determined with reference to the appended claims, along with the full scope of equivalents to which such claims are entitled.

We claim:

1. A thermal interface module device coupleable to a heat sink element, the thermal interface module comprising:
a first interface;
a second interface;
a housing coupleable between the first interface and the second interface;
an interface module configured to provide a thermal path to the heat sink element;
a first film coupleable between the first interface and the interface module; and
a second film coupleable between the second interface and the interface module.

2. The thermal interface module device of claim 1, wherein the first interface is an energized interface plate.

3. The thermal interface module device of claim 1, wherein the second interface is a grounded interface plate.

4. The thermal interface module device of claim 1, wherein the interface module is a ceramic material.

5. The thermal interface module device of claim 1, wherein the interface module is an aluminum oxide material.

6. The thermal interface module device of claim 5, wherein the aluminum oxide material is alumina.

7. The thermal interface module device of claim 1, wherein the first film and the second film are configured to provide isolation layers.

8. A system for providing an electrically isolating thermal interface, comprising:
a power source;
a thermal dissipation element; and
a thermal interface module device coupleable between the power source and the thermal dissipation element, the thermal interface module device including:
a first interface coupleable to the power source;
a second interface coupleable to the thermal dissipation element;
a housing coupleable between the first interface and the second interface;
an interface module configured to provide a thermal path from the first interface to the second interface;
a first film coupleable between the first interface and the interface module; and
a second film coupleable between the second interface and the interface module.

9. The system of claim 8, wherein the first interface is an energized interface plate.

10. The system of claim 8, wherein the second interface is a grounded interface plate.

11. The system of claim 8, wherein the interface module is a ceramic material.

12. The system of claim 8, wherein the interface module is an aluminum oxide material.

13. The system of claim 12, wherein the aluminum oxide material is alumina.

14. The system of claim 8, wherein the first film and the second film are configured to provide isolation layers.

15. The system of claim 8, wherein the thermal dissipation element is configured to dissipate heat shared between phases of a plurality of power sources.

16. A method for providing a thermal interface module device between a power source and a thermal dissipation element, comprising:
providing a first interface in contact with the power source;
providing a second interface in contact with the thermal dissipation element;
providing a housing between the first interface and the second interface;
providing an interface module implementing a thermal path from the first interface and the second interface;
providing a first film in contact with the first interface and the interface module; and
providing a second film in contact with the second interface and the interface module.
